(19) United States
(12) Patent Application Publication
(10) Pub. No.: US 2026/0164940 A1
(43) Pub. Date: Jun. 11, 2026

(54) DISPLAY DEVICE, ELECTRONIC DEVICE INCLUDING THE SAME AND METHOD FOR FABRICATING DISPLAY DEVICE

(71) Applicant: Samsung Display Co., LTD., Yongin-si (KR)

(72) Inventors: Sa Min LEE, Yongin-si (KR); A Rong KIM, Yongin-si (KR); Young Min MOON, Yongin-si (KR); Won Je CHO, Yongin-si (KR)

(21) Appl. No.: 19/304,002

(22) Filed: Aug. 19, 2025

(30) Foreign Application Priority Data
Dec. 5, 2024 (KR) 10-2024-0179083

(51) Int. Cl. H10K 59/122; H10H 29/01; H10H 29/37; H10H 29/80; H10K 59/12; H10K 59/80; H10K 77/10; H10K 102/00

(52) U.S. Cl. CPC H10K 59/122; H10H 29/012; H10H 29/37; H10H 29/8321; H10K 59/1201; H10K 59/80515; H10K 59/80521; H10K 77/111; H10K 2102/311

(57) ABSTRACT

A display device includes a substrate including a light emitting area and a non-light emitting area; an anode electrode disposed on one surface of the substrate to overlap the light emitting area; a light emitting layer disposed on the anode electrode; an element insulating layer disposed on the light emitting layer and defining an opening; a cathode electrode disposed on the element insulating layer and in contact with the light emitting layer in a portion overlapping the opening; and an insulating pattern disposed to surround the opening in a plan view and disposed between the light emitting layer and the element insulating layer, where the insulating pattern includes a bending portion bent in a direction perpendicular to the one surface of the substrate.

This application claims priority to Korean Patent Application No. 10-2024-0179083 filed on Dec. 5, 2024, and all the benefits accruing therefrom under 35 U.S.C. § 119, the content of which in its entirety is herein incorporated by reference.

### BACKGROUND

### 1. Field

The present disclosure relates to a display device, an electronic device including the display device, and a method for fabricating the display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions. The display devices may be flat panel display devices such as liquid crystal display devices, field emission display devices, or organic light emitting display devices. Among the flat panel display devices, the light emitting display device may include a light emitting element in which each of the pixels of a display panel may emit light by itself, thereby displaying an image without a backlight unit providing the light to the display panel.

As various electronic devices have recently developed, the demand for high-resolution display devices is increasing. Since the high-resolution display devices is desired to have high pixel integration, the spacing between light emitting elements overlapping each light emitting area may be narrowed. Accordingly, the high-resolution display device may be formed by a patterning process of forming individual pixels rather than a mask process.

### SUMMARY

Embodiments of the present disclosure provide a high-resolution display device having a plurality of light emitting elements spaced apart from each other within a narrow area.

However, embodiments of the present disclosure are not restricted to those set forth herein. The above and other embodiments of the present disclosure will become more apparent to one of ordinary skill in the art to which the present disclosure pertains by referring the detailed description of the present disclosure given below.

In an embodiment of the disclosure, a display device includes a substrate including a light emitting area and a non-light emitting area; an anode electrode disposed on one surface of the substrate to overlap the light emitting area; a light emitting layer disposed on the anode electrode; an element insulating layer disposed on the light emitting layer and defining an opening; a cathode electrode disposed on the element insulating layer and in contact with the light emitting layer in a portion overlapping the opening; and an insulating pattern disposed to surround the opening in a plan view and disposed between the light emitting layer and the element insulating layer, where the insulating pattern includes a bending portion bent in a direction perpendicular to the one surface of the substrate.

In an embodiment, the insulating pattern may be in contact with the light emitting layer, the cathode electrode, and the element insulating layer, and the insulating pattern is completely surrounded by the light emitting layer, the cathode electrode, and the element insulating layer.

In an embodiment, a length of the bending portion of the insulating pattern may be about 50 nanometers or greater and about 500 nanometers or less.

In an embodiment, the insulating pattern may include at least one selected from silicon nitride, silicon oxide, and silicon oxynitride.

In an embodiment, the insulating pattern may include a first insulating pattern in contact with the light emitting layer; and a second insulating pattern disposed between the first insulating pattern and the element insulating layer.

In an embodiment, a tensile stress value of the second insulating pattern may be greater than a tensile stress value of the first insulating pattern.

In an embodiment, a first bending portion included in the first insulating pattern and a second bending portion included in the second insulating pattern may be in contact with each other, and the first bending portion and the second bending portion are bent in the same direction.

In an embodiment, a side surface of the insulating pattern facing the opening may be completely covered by the cathode electrode.

In an embodiment, an inclined angle formed by the one surface of the substrate and a side surface of the light emitting layer may be about 60 degrees or greater and about 90 degrees or less.

In an embodiment, the element insulating layer may be in contact with and covers the insulating pattern and the side surface of the light emitting layer.

In an embodiment, the bending portion of the insulating pattern may protrude further in a direction toward the non-light emitting area than the side surface of the light emitting layer does.

In an embodiment, the display device may further include a pixel definition layer covering an edge of the anode electrode and defining an opening, where a portion of the light emitting layer in the opening defined by the pixel defining layer may be in contact with the anode electrode, and a portion of the light emitting layer exposed through the opening defined by the element insulating layer may be in contact with the cathode electrode.

In an embodiment of the disclosure, a method for fabricating a display device includes: forming a light emitting layer and insulating layers on a substrate including an anode electrode; removing a portion of the insulating layers and the light emitting layer by performing a dry etching process; forming a bending portion of the insulating layers by performing an ashing process; forming an insulating pattern after forming an element insulating layer defining an opening; and forming a cathode electrode on the light emitting layer and the element insulating layer, where the insulating layers include a first insulating layer and a second insulating layer, and a tensile stress value of the second insulating layer may be greater than a tensile stress of the first insulating layer.

In an embodiment, in the forming the bending portion of the insulating layers by performing the ashing process, edges of the first insulating layer and the second insulating layer may be bent in a direction perpendicular to one surface of the substrate.

In an embodiment of the disclosure, an electronic device includes a display device including a substrate including a light emitting area and a non-light emitting area; and at least one selected from a display module, a processor, a memory and a power module, which is connected to the display device, where the display device includes: an anode electrode disposed on one surface of the substrate to overlap the light emitting area; a light emitting layer disposed on the anode electrode; an element insulating layer disposed on the light emitting layer and defining an opening; a cathode electrode disposed on the element insulating layer and in contact with the light emitting layer in a portion overlapping the opening; and an insulating pattern disposed to surround the opening in a plan view and disposed between the light emitting layer and the element insulating layer, and the insulating pattern includes a bending portion bent in a direction perpendicular to the one surface of the substrate.

In an embodiment, the insulating pattern may be in contact with the light emitting layer, the cathode electrode, and the element insulating layer, and the insulating pattern is completely surrounded by the light emitting layer, the cathode electrode, and the element insulating layer.

In an embodiment, a length of the bending portion of the insulating pattern may be about 50 nanometers or greater and about 500 nanometers or less.

In an embodiment, the insulating pattern may include at least one selected from silicon nitride, silicon oxide, and silicon oxynitride.

In an embodiment, the insulating pattern may include a first insulating pattern in contact with the light emitting layer; and a second insulating pattern disposed in contact between the first insulating pattern and the element insulating layer.

In an embodiment, a tensile stress value of the second insulating pattern may be greater than a tensile stress value of the first insulating pattern.

According to embodiments of the display device, a high-resolution display device having a plurality of light emitting elements disposed to be spaced apart from each other within a narrow area may be provided.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of embodiments of the present disclosure will become more apparent by describing in detail embodiments thereof with reference to the attached drawings, in which:

FIG. 1 is a perspective view illustrating a display device according to an embodiment;

FIG. 2 is a schematic cross-sectional view of the display device of FIG. 1;

FIG. 3 is a plan view illustrating an arrangement of a plurality of pixels in a display area of FIG. 2;

FIG. 4 is a schematic cross-sectional view taken along line X1-X1′ of FIG. 3;

FIG. 5 is an enlarged schematic cross-sectional view of a display element layer overlapping a first light emitting area in FIG. 4;

FIG. 6 is an enlarged cross-sectional view of area ‘A’ in FIG. 5;

FIG. 7 is a schematic cross-sectional view taken along line X1-X1′ of FIG. 3 according to another embodiment;

FIG. 8 is an enlarged schematic cross-sectional view of a display element layer overlapping a first light emitting area in FIG. 7;

FIG. 9 is a schematic cross-sectional view taken along line X1-X1′ of FIG. 3 according to another embodiment;

FIG. 10 is a flowchart illustrating a method for fabricating the display element layer of FIG. 4;

FIG. 11 is a cross-sectional view illustrating process S100 of FIG. 10;

FIGS. 12 to 14 are cross-sectional views illustrating process S200 of FIG. 10;

FIGS. 15 and 16 are cross-sectional views illustrating process S300 of FIG. 10;

FIGS. 17 to 20 are cross-sectional views illustrating process S400 of FIG. 10;

FIG. 21 is a cross-sectional view illustrating process S500 of FIG. 10;

FIG. 22 is a block diagram of an electronic device according to an embodiment; and

FIG. 23 illustrates schematic diagrams of electronic devices according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

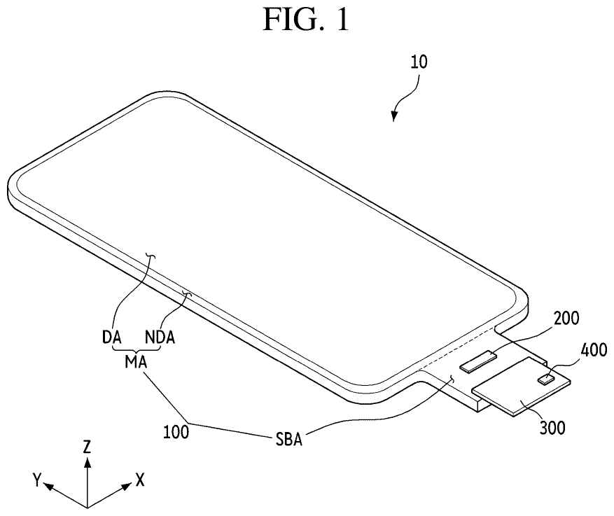

FIG. 1 is a perspective view illustrating a display device according to an embodiment.

Referring to FIG. 1, an embodiment of a display device 10 displays a moving image or a still image. The display device 10 may refer to any electronic device that provides a display screen. For example, the display device 10 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like that provide the display screen.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) means a horizontal direction in the drawings, the second direction (Y-axis direction) means a vertical direction in the drawings, and the third direction (Z-axis direction) means upper and lower directions in the drawings, that is, a thickness direction of the display device 10. In the following specification, unless otherwise specified, the term “direction” may refer to both directions toward opposite sides extending along the direction. In addition, when both “directions” extending to the opposite sides to be distinguished from each other, one side will be referred to as “one side in the direction” and the other side will be referred to as “the other side in the direction”. In FIG. 1, a direction in which an arrow indicating a direction is directed is referred to as one side, and an opposite direction thereof is referred to as the other side.

Hereinafter, for convenience of description, in referring to surfaces of each member constituting the display device 10, one surface facing one side in a direction in which an image is displayed, that is, in the third direction (Z-axis direction) is referred to as an upper surface, and an opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing a relative position of each member of the display device 10, one side in the third direction (Z-axis direction) may be referred to as an upper side and the other side in the third direction (Z-axis direction) may be referred to as a lower side.

A shape (or planar shape) of the display device 10 may be variously changed. In an embodiment, for example, the display device 10 may have a shape such as a rectangle with a long width, a rectangle with a long length, a square, a quadrangle with rounded corners (vertices), other polygons, or a circle.

In an embodiment, the display device 10 may include a display panel 100, a display driver 200, a circuit board 300, and a touch driver 400.

The display panel 100 may include a main area MA and a sub-area SBA. The main area MA may include a display area DA including pixels for displaying an image and a non-display area NDA arranged around the display area DA. The main area MA and the sub-area SBA may include a flexible material that may be bent, folded, rolled, or the like.

The display area DA is an area in which an image may be displayed, and the non-display area NDA is an area in which no image is displayed. The display area DA may also be referred to as an active area, and the non-display area NDA may also be referred to as a non-active area. The display area DA may generally occupy the center of the display device 10. The non-display area NDA may be an area outside the display area DA. The non-display area NDA may be defined as an edge (or peripheral) area of the display panel 100. The non-display area NDA may include lines that supply signals to the display area DA and lines connecting the display driver 200 and the display area DA.

The sub-area SBA may be an area extending from one side of the main area MA. When the sub-area SBA is bent, the sub-area SBA may overlap the main area MA in a thickness direction (e.g., a third direction (Z-axis direction)). The sub-area SBA may include the display driver 200 and a display pad connected to the circuit board 300. In another embodiment, the sub-area SBA may be omitted, and the display driver 200 and the display pad may be positioned or disposed in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. In an embodiment, for example, the display driver 200 may be arranged in the sub-area SBA, and may overlap the main area MA in the thickness direction by bending of the sub-area SBA. In another embodiment, for example, the display driver 200 may be mounted on the circuit board 300.

The circuit board 300 may be attached onto the display pad of the display panel 100 using an anisotropic conductive film (ACF). The circuit board 300 may be electrically connected to the display pad. The circuit board 300 may be a flexible film such as a flexible printed circuit board, a printed circuit board, or a chip on film.

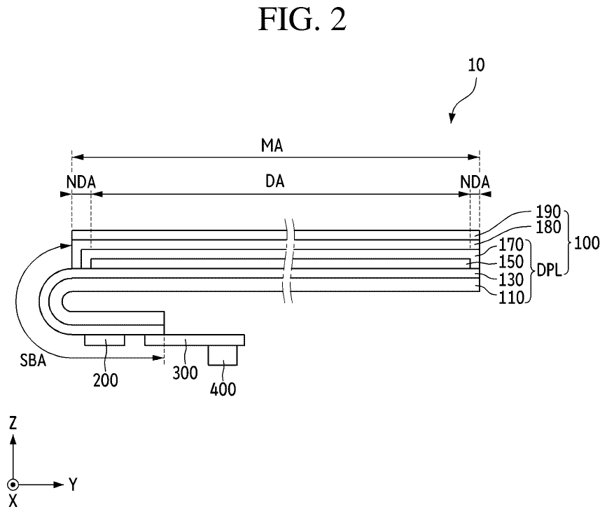

The touch driver 400 may be mounted on the circuit board 300. The touch driver 400 may be connected to a touch sensor layer (“180” in FIG. 2) of the display panel 100.

FIG. 2 is a schematic cross-sectional view of the display device of FIG. 1.

Referring to FIG. 2, an embodiment of the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, rolled, or the like. In an embodiment, for example, the substrate 110 may include a polymer resin such as polyimide (PI), but is not limited thereto. In another embodiment, the substrate 110 may include a glass material or a metal material.

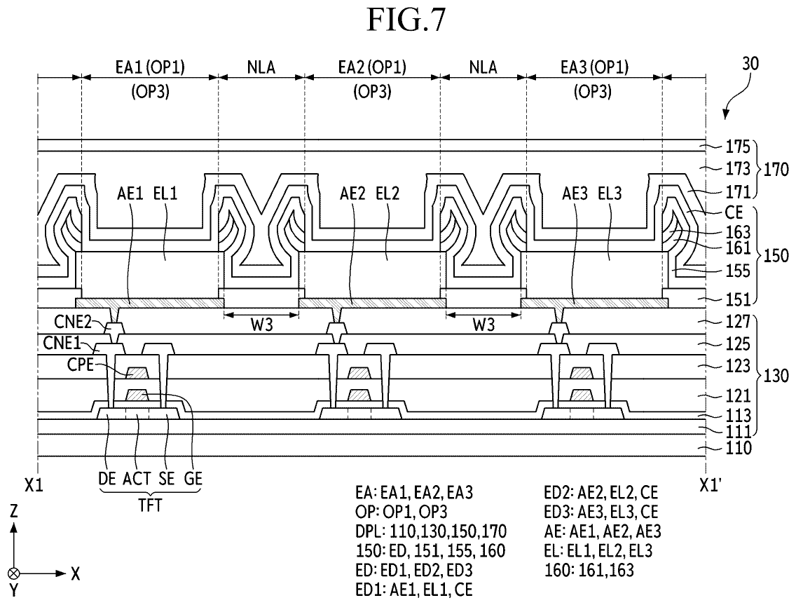

The thin film transistor layer 130 may be positioned (or disposed) on the substrate 110. The thin film transistor layer 130 may be positioned in a portion overlapping the display area DA, the non-display area NDA, and the sub-area SBA. The thin film transistor layer 130 may include a plurality of thin film transistors (“TFT” in FIG. 7).

The display element layer 150 may be positioned on the thin film transistor layer 130. The display element layer 150 may be positioned in a portion overlapping the display area DA. The display element layer 150 may include, but is not limited to, at least one selected from an organic light emitting diode (LED) including an organic light emitting layer, a quantum dot LED including a quantum dot light emitting layer, an inorganic LED including an inorganic semiconductor, and a micro LED.

The thin film encapsulation layer 170 may be positioned on the display element layer 150. The thin film encapsulation layer 170 may be positioned in a portion overlapping the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be positioned on the thin film encapsulation layer 170. The touch sensor layer 180 may be positioned in a portion overlapping the display area DA and the non-display area NDA. The touch sensor layer 180 may sense a user's touch in a mutual capacitance method or a self-capacitance method.

The color filter layer 190 may be positioned on the touch sensor layer 180. The color filter layer 190 may be positioned in a portion overlapping the display area DA and the non-display area NDA. The color filter layer 190 may absorb a portion of light introduced from the outside of the display device 10 to reduce reflected light caused by external light. Therefore, the color filter layer 190 may effectively prevent color distortion caused by reflection of external light.

As the color filter layer 190 is directly arranged on the touch sensor layer 180, the display device 10 may not include a separate substrate for the color filter layer 190. Therefore, the display device 10 may have a relatively small thickness. The color filter layer 190 may also be omitted depending on the embodiment.

In an embodiment, as illustrated in FIG. 2, a portion of the display layer DPL overlapping the sub-area SBA may be bent. In a state where a portion of the display layer DPL is bent, the display driver 200, circuit board 300, and touch driver 400 may overlap the main area MA in the third direction (Z-axis direction).

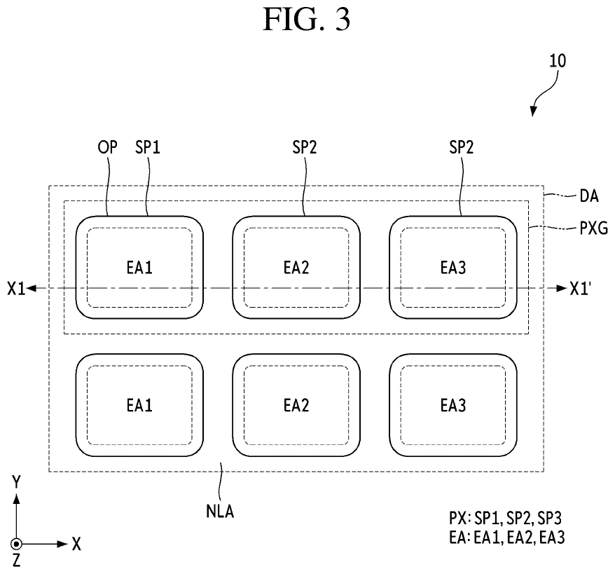

FIG. 3 is a plan view illustrating an arrangement of a plurality of pixels in a display area of FIG. 2.

Referring to FIG. 3, in an embodiment, a plurality of pixels PX may be disposed or formed in a portion overlapping the display area DA.

In an embodiment, the pixel PX may include a light emitting area EA defined by an opening OP. The opening OP will be described later.

The light emitting area EA may include a first light emitting area EA1, a second light emitting area EA2 and a third light emitting area EA3 that emit light of different colors, respectively. In an embodiment, the first light emitting area EA1 may emit red light of a first color, the second light emitting area EA2 may emit green light of a second color, and the third light emitting area EA3 may emit blue light of a third color, but the present disclosure is not limited thereto.

In some embodiments, a first sub-pixel SP1 including at least one first light emitting area EA1, a second sub-pixel SP2 including at least one second light emitting area EA2, and a third sub-pixel SP3 including at least one third light emitting area EA3 that are arranged adjacent to each other may configure or collectively define one pixel group PXG. The pixel group PXG may be a minimum unit that emits white light. However, the type and/or number of light emitting areas EA constituting the pixel group PXG may be variously changed or modified according to embodiments.

In an embodiment, as shown in FIG. 3, the size and shape of each of the first to third light emitting areas EA1, EA2, and EA3 may be the same as each other, but the present disclosure is not limited thereto. In embodiments, the size and shape of each of the first to third light emitting areas EA1, EA2, and EA3 may be freely adjusted according to desired characteristics.

The non-light emitting area NLA according to an embodiment may be positioned to surround each of the first to third light emitting areas EA1, EA2, and EA3 in a plan view or when viewed in the third direction (i.e., Z-axis direction). The non-light emitting area NLA may assist in preventing the light emitted from each of the first to third light emitting areas EA1, EA2, and EA3 from being mixed.

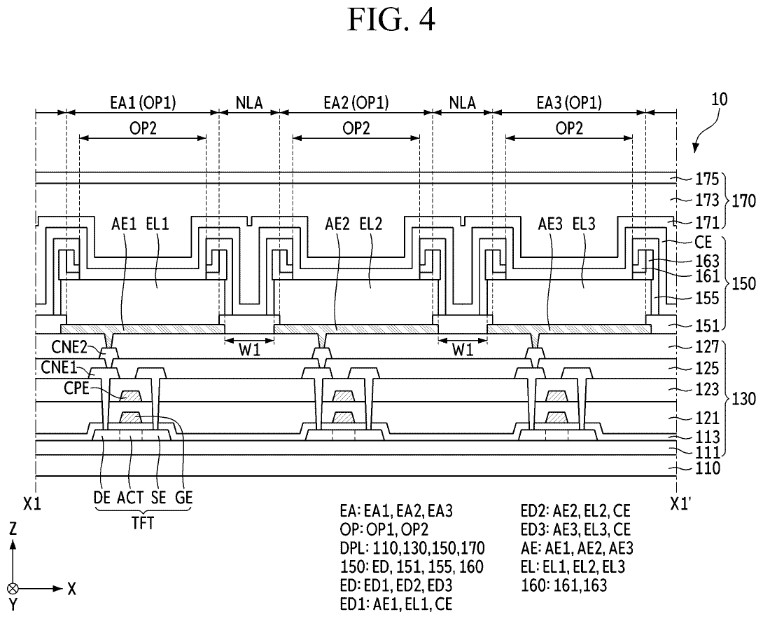

FIG. 4 is a schematic cross-sectional view taken along line X1-X1′ of FIG. 3. FIG. 4 is a cross-sectional view of a portion of the display device overlapping the display area of FIG. 3, which illustrates a schematic cross-section of the display layer.

Referring to FIG. 4, in an embodiment, the thin film transistor layer 130 may be positioned (or disposed) on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be positioned on the substrate 110. The first buffer layer 111 may include an inorganic film capable of preventing permeation of air or moisture. In an embodiment, for example, the first buffer layer 111 may include a plurality of inorganic films alternately stacked.

The thin film transistor TFT may be arranged on the first buffer layer 111, and may constitute a pixel circuit connected to each of the plurality of pixels. In an embodiment, for example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be positioned on the first buffer layer 111. The active layer ACT may overlap the gate electrode GE in the third direction (Z-axis direction), and may be insulated from the gate electrode GE by the gate insulating layer 113. In a portion of the active layer ACT, a material of the active layer ACT may become a conductor to form the source electrode SE and the drain electrode DE.

The gate electrode GE may be positioned on the gate insulating layer 113. The gate electrode GE may overlap the active layer ACT with the gate insulating layer 113.

The gate insulating layer 113 may be positioned on the active layer ACT. The gate insulating layer 113 may cover the active layer ACT and the first buffer layer 111, and may insulate the active layer ACT and the gate electrode GE from each other. The gate insulating layer 113 may be provided with a contact hole through which the first connection electrode CNE1 extends or is disposed.

The first interlayer insulating layer 121 may cover the gate electrode GE and the gate insulating layer 113. The first interlayer insulating layer 121 may be provided with a contact hole through which the first connection electrode CNE1 extends or is disposed. The contact hole of the first interlayer insulating layer 121 may be connected to the contact hole of the gate insulating layer 113 and a contact hole of the second interlayer insulating layer 123.

The capacitor electrode CPE may be positioned on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may be provided with a contact hole through which the first connection electrode CNE1 extends or is disposed. The contact hole of the second interlayer insulating layer 123 may be connected to the contact hole of the first interlayer insulating layer 121 and the contact hole of the gate insulating layer 113.

The first connection electrode CNE1 may be positioned on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate insulating layer 113 and be in contact with the drain electrode DE of the thin film transistor TFT.

The first via layer 125 may cover the first connection electrode CNE1 and the second interlayer insulating layer 123. The first via layer 125 may planarize a lower structure. The first via layer 125 may be provided with a contact hole through which the second connection electrode CNE2 extends or is disposed.

The second connection electrode CNE2 may be positioned on the first via layer 125. The second connection electrode CNE2 may be inserted into the contact hole formed in the first via layer 125 and be in contact with the first connection electrode CNE1. The second connection electrode CNE2 may electrically connect the first connection electrode CNE1 and an anode electrode AE to each other.

The second via layer 127 may cover the second connection electrode CNE2 and the first via layer 125. The second via layer 127 may be provided with a contact hole through which the anode electrode AE extends or is disposed.

The display element layer 150 may be positioned on the second via layer 127. The display element layer 150 may include a light emitting element ED, a pixel defining layer 151, an element insulating layer 155, and an insulating pattern 160.

The light emitting area EA included in the display device 10 may be defined by an opening OP. The opening OP may include an opening OP1 defined by the pixel defining layer 151 and an opening OP2 defined by the insulating pattern 160. The opening OP will be described later.

The light emitting element ED may include a first light emitting element ED1 arranged in the first light emitting area EA1, a second light emitting element ED2 arranged in the second light emitting area EA2, and a third light emitting element ED3 arranged in the third light emitting area EA3.

The first light emitting element ED1 may include a first anode electrode AE1, a first light emitting layer EL1, and a cathode electrode CE, the second light emitting element ED2 may include a second anode electrode AE2, a second light emitting layer EL2, and a cathode electrode CE, and the third light emitting element ED3 may include a third anode electrode AE3, a third light emitting layer EL3, and a cathode electrode CE. The cathode electrode CE may be a common electrode.

The light emitting elements ED overlapping the first to third light emitting areas EA1, EA2, and EA3, respectively, may emit light of different colors from each other depending on the material of the light emitting layer EL. In an embodiment, for example, the first light emitting element ED1 may emit red light, the second light emitting element ED2 may emit green light, and the third light emitting element ED3 may emit blue light.

The anode electrode AE may be positioned on the second via layer 127. The anode electrode AE may be electrically connected to the drain electrode DE of the thin film transistor TFT through the first and second connection electrodes CNE1 and CNE2.

The anode electrode AE may include a first anode electrode AE1 arranged in the first light emitting area EA1, a second anode electrode AE2 arranged in the second light emitting area EA2, and a third anode electrode AE3 arranged in the third light emitting area EA3. The first anode electrode AE1, the second anode electrode AE2, and the third anode electrode AE3 may be positioned to be spaced apart from each other.

The anode electrode AE may have a stacked film structure in which a material layer having a high work function, including or made of indium tin oxide (ITO), indium zinc oxide (IZO), zinc oxide (ZnO), or indium oxide (In₂O₃) and a reflective material layer including or made of silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or mixtures thereof are stacked. In an embodiment, for example, the anode electrode AE may have a multilayer structure of ITO/Mg, ITO/MgF, ITO/Ag, and ITO/Ag/ITO, but is not limited thereto.

In an embodiment, the pixel defining layer 151 may be positioned in contact with the second via layer 127 in a portion overlapping the non-light emitting area NLA. The pixel defining layer 151 may cover an edge of the anode electrode AE.

The pixel defining layer 151 may define the opening OP1, that is, the opening OP1 may be defined through the pixel defining layer 151. The pixel defining layer 151 may be positioned to surround the opening OP1. The pixel defining layer 151 may expose the anode electrode AE in a portion overlapping the opening OP1.

The pixel defining layer 151 may insulate and separate the first anode electrode AE1, the second anode electrode AE2, and the third anode electrode AE3 from each other.

The pixel defining layer 151 may include an inorganic insulating material. In an embodiment, for example, the pixel defining layer 151 may include at least one selected from silicon nitride, silicon oxide, and silicon oxynitride.

In an embodiment, the light emitting layer EL may be positioned on the anode electrode AE. The light emitting layer EL may be in contact with the anode electrode AE in a portion overlapping the opening OP1, and may be positioned on the pixel defining layer 151 in a portion that does not overlap the opening OP1.

The light emitting layer EL may include a first light emitting layer EL1, a second light emitting layer EL2, and a third light emitting layer EL3 arranged in the first to third light emitting areas EA1, EA2, and EA3, respectively. The first light emitting layer EL1, the second light emitting layer EL2, and the third light emitting layer EL3 may emit light of different colors. In an embodiment, for example, the first light emitting layer EL1 may emit red light, the second light emitting layer EL2 may emit green light, and the third light emitting layer EL3 may emit blue light, but the present disclosure is not limited thereto.

The light emitting layer EL may be formed through a photo lithography process during the fabricating process. In other words, the light emitting layer EL may be formed through a photo process and an etching process without using a separate fine metal mask. The fabricating process thereof will be described later.

In general, a display device applied to a high-resolution product may have a plurality of light emitting elements ED formed within a narrow area. This may mean that a distance between the plurality of light emitting elements ED is narrowly formed. Accordingly, disposing the plurality of light emitting elements ED to have a minimum separation distance may be a key factor in the high-resolution display.

The display device 10 according to an embodiment may efficiently dispose the plurality of light emitting layers EL within a minimum area by forming the light emitting layer EL included in the light emitting element ED through the photo lithography process. In other words, the display device 10 according to an embodiment may minimally form a spacing distance W1 between the first to third light emitting layers EL1, EL2, and EL3 by forming the light emitting layer EL included in the light emitting element ED through the photo lithography process.

The element insulating layer 155 may be positioned on the pixel defining layer 151 and the light emitting layer EL. The element insulating layer 155 may cover an edge of the light emitting layer EL. The element insulating layer 155 may be in contact with the pixel defining layer 151 and the light emitting layer EL.

The element insulating layer 155 may define the opening OP2. The element insulating layer 155 may be positioned to surround the opening OP2. The element insulating layer 155 may expose the light emitting layer EL in a portion overlapping the opening OP2.

The element insulating layer 155 may include an inorganic insulating material. In an embodiment, for example, the element insulating layer 155 may include at least one selected from silicon nitride, silicon oxide, and silicon oxynitride.

The cathode electrode CE may be positioned on the light emitting layer EL and the element insulating layer 155. The cathode electrode CE may be in contact with the light emitting layer EL in a portion overlapping the opening OP2, and may cover the element insulating layer 155 and the pixel defining layer 151 in a portion that does not overlap the opening OP2. In other words, the cathode electrode CE may be entirely formed on the first light emitting layer EL1, the second light emitting layer EL2, and the third light emitting layer EL3, and may be a common electrode.

The cathode electrode CE may receive a common voltage or a low potential voltage. Specifically, when the anode electrode AE receives a voltage corresponding to the data voltage and the cathode electrode CE receives the low potential voltage, the light emitting layer EL may emit light as a potential difference is formed between the anode electrode AE and the cathode electrode CE.

The insulating pattern 160 may be positioned on the light emitting layer EL. In an embodiment, the insulating pattern 160 may be positioned between the light emitting layer EL and the element insulating layer 155 in the third direction (Z-axis direction). The insulating pattern 160 may be positioned to surround the opening OP2.

In the cross-section, the insulating pattern 160 may be in contact with the light emitting layer EL, the element insulating layer 155, and the cathode electrode CE, and may be completely surrounded by the light emitting layer EL, the element insulating layer 155, and the cathode electrode CE.

The insulating pattern 160 may be formed to protect the light emitting layer EL from repeated etching processes during the process of fabricating the display device 10. Accordingly, the insulating pattern 160 may be temporarily formed to entirely cover the upper surface of the light emitting layer EL during the process of fabricating the display device 10, and then formed into the shape illustrated through a subsequent process.

In an embodiment, the insulating pattern 160 may include a bending portion bent toward one side in the third direction (Z-axis direction).

In an embodiment, for example, where the insulating pattern 160 is formed to protrude further than a side surface of the light emitting layer EL in a direction parallel to the first direction (X-axis direction), this may increase the spacing distance W1 between the first to third light emitting layers EL1, EL2, and EL3. Accordingly, the display device 10 according to an embodiment may assist in minimizing the spacing distance W1 between the first to third light emitting layers EL1, EL2, and EL3 by forming the insulating pattern 160 to be bent toward one side in the third direction (Z-axis direction). A shape of the insulating pattern 160 will be described later.

The insulating pattern 160 may include a first insulating pattern 161 and a second insulating pattern 163. The first insulating pattern 161 may be positioned in contact with the light emitting layer EL, and the second insulating pattern 163 may be positioned in contact between the first insulating pattern 161 and the element insulating layer 155.

The first insulating pattern 161 may include an inorganic insulating material. In an embodiment, for example, the first insulating pattern 161 may include at least one selected from silicon nitride, silicon oxynitride, and silicon oxide.

The second insulating pattern 163 may include an inorganic insulating material. In an embodiment, for example, the second insulating pattern 163 may include at least one selected from silicon nitride, silicon oxynitride, and silicon oxide.

The thin film encapsulation layer 170 may be positioned on the display element layer 150. The thin film encapsulation layer 170 may be positioned in a portion overlapping the light emitting area EA and the non-light emitting area NLA. The thin film encapsulation layer 170 may include a first encapsulation layer 171, a second encapsulation layer 173, and a third encapsulation layer 175 that are sequentially stacked.

The first encapsulation layer 171 may be positioned on the cathode electrode CE. The first encapsulation layer 171 may have a uniform thickness according to a profile of a lower structure and may cover the lower structure. Therefore, the first encapsulation layer 171 may include steps or stepped structures.

The first encapsulation layer 171 may effectively prevent oxygen or moisture from permeating into the light emitting element ED.

The first encapsulation layer 171 may include an inorganic insulating material, for example, at least one selected from aluminum oxide, titanium oxide, tantalum oxide, hafnium oxide, zinc oxide, silicon oxide, silicon nitride, and silicon oxynitride.

The second encapsulation layer 173 may be positioned on the first encapsulation layer 171. The second encapsulation layer 173 may planarize the steps formed by the first encapsulation layer 171. In addition, the second encapsulation layer 173 may protect the display element layer 150 from foreign substances.

The second encapsulation layer 173 may include a polymer-based material. In an embodiment, for example, the second encapsulation layer 173 may include a silicon-based resin, an acrylic-based resin, an epoxy-based resin, or a mixture thereof.

The third encapsulation layer 175 may be positioned on the second encapsulation layer 173. The third encapsulation layer 175 may include one or more inorganic insulating materials and may effectively prevent oxygen or moisture from permeating into the display element layer 150 and the first encapsulation layer 171. The third encapsulation layer 175 may include a same material as the first encapsulation layer 171. any repetitive detailed descriptions of the material of the third encapsulation layer 175 will be omitted.

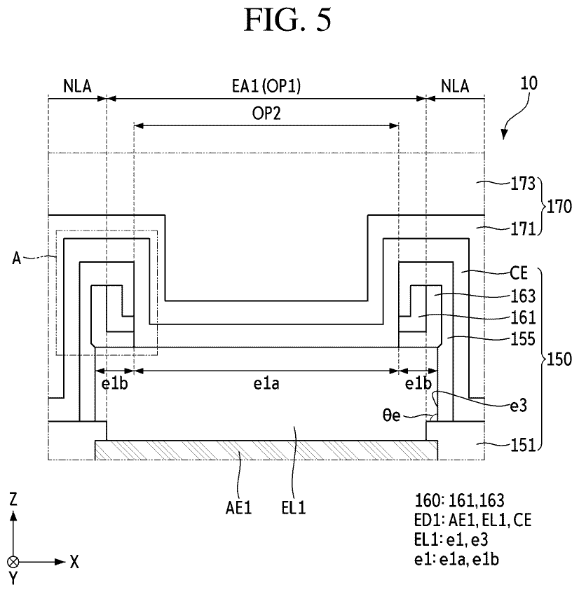

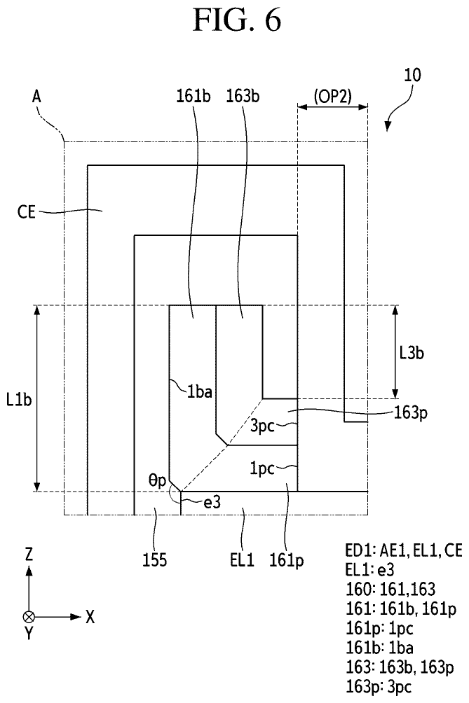

FIG. 5 is an enlarged schematic cross-sectional view of a display element layer overlapping a first light emitting area in FIG. 4 and FIG. 6 is an enlarged cross-sectional view of area ‘A’ in FIG. 5.

Referring to FIGS. 5 and 6, the display element layer 150 according to an embodiment may include a first light emitting element ED1, a pixel defining layer 151, an element insulating layer 155, and an insulating pattern 160 in a portion overlapping the first light emitting area EA1.

The first light emitting layer EL1 included in the first light emitting element ED1 may include an upper surface e1 and a side surface e3. The upper surface e1 may be one surface facing the cathode electrode CE, and the side surface e3 may be one surface facing the element insulating layer 155 toward the non-light emitting area NLA. The upper surface e1 and the side surface e3 may be connected to each other.

In an embodiment, the side surface e3 of the first light emitting layer EL1 may be an inclined surface. The side surface e3 of the first light emitting layer EL1 may have a high taper angle. In an embodiment, for example, an inclination angle θe formed by the side surface e3 of the first light emitting layer EL1 and one surface of the pixel defining layer 151 may be in a range from about 60 degrees or greater to about 90 degrees or less.

In an embodiment, as described above, the light emitting layer EL may be formed by the photo lithography process. Accordingly, the first light emitting layer EL1 may have a side surface e3 having a substantially predetermined shape without tail defects (or an elongated, tail-like extension) due to mask shadow.

The upper surface e1 of the first light emitting layer EL1 may include a first portion e1a and a second portion e1b depending on the contact structure. The first portion e1a may be a portion in contact with the cathode electrode CE, and the second portion e1b may be a portion in contact with the insulating pattern 160. The second portion e1b may be in contact with the first insulating pattern 161 of the insulating pattern 160.

The first portion e1a may be positioned in the center of the upper surface e1, and the second portion e1b may be positioned at an edge of the upper surface e1 or define an edge portion of the upper surface e1. The second portion e1b may be positioned to surround the first portion e1a in a plan view or when viewed in the third direction (Z-axis direction).

In an embodiment, as described above, the first insulating pattern 161 and the second insulating pattern 163 may include an inorganic insulating material.

In an embodiment, tensile stress in the second insulating pattern 163 may be greater than tensile stress in the first insulating pattern 161. In an embodiment, for example, when the first insulating pattern 161 is an inorganic material including compressive stress properties, the second insulating pattern 163 may have tensile stress having a value of about zero (0) or greater. In another embodiment, for example, when the first insulating pattern 161 is an inorganic material including tensile stress properties, the second insulating pattern 163 may have tensile stress whose absolute value is greater than that in the first insulating pattern 161.

In an embodiment, as illustrated in FIG. 6, the first insulating pattern 161 included in the insulating pattern 160 may have a flat portion 161p and a bending (or bent) portion 161b. The flat portion 161p and the bending portion 161b are formed integrally with each other as a single unitary indivisible part, but may have different positional shapes. In an embodiment, for example, the flat portion 161p may be positioned or extending in the first direction (X-axis direction) or in a direction parallel to the substrate 110, and the bending portion 161b may be positioned or extending in the third direction (Z-axis direction) or in a direction perpendicular to the substrate 110. In other words, the first insulating pattern 161 may have an ‘L’ shape or a shape mirror-symmetrical to the ‘L’ shape.

In an embodiment, the flat portion 161p may be in contact with the first light emitting layer EL1. The flat portion 161p may include a side surface 1pc facing or defining the opening OP2. The side surface 1pc of the flat portion 161p may be in contact with the cathode electrode CE and may be entirely covered by the cathode electrode CE.

In an embodiment, the bending portion 161b may extend from the flat portion 161p and may not be in contact with the first light emitting layer EL1. The bending portion 161b may be in contact with the element insulating layer 155.

In an embodiment, the bending portion 161b may include a first surface 1ba. The first surface 1ba of the bending portion 161b may be one surface of the bending portion 161b in contact with the element insulating layer 155.

In an embodiment, an inclination angle θp formed by the first surface 1ba of the bending portion 161b and the side surface e3 of the first light emitting layer EL1 at a point where the first surface 1ba of the bending portion 161b and the side surface e3 of the first light emitting layer EL1 meat each other may be an obtuse angle.

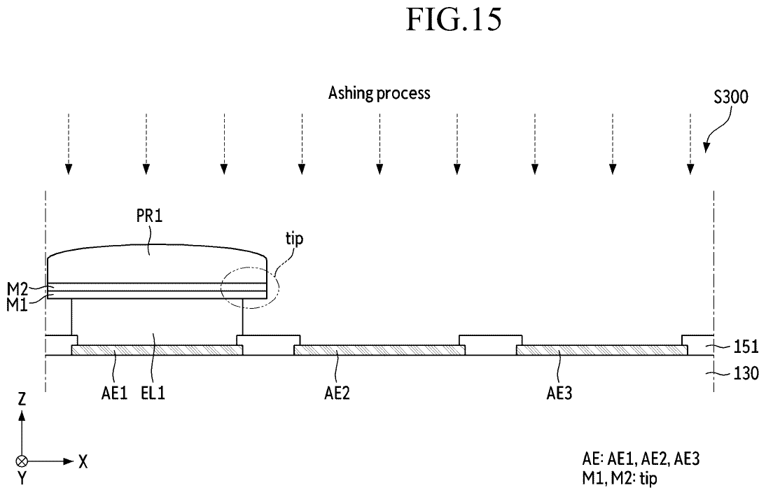

In the process of fabricating the display device 10, the bending portion 161b may be temporarily positioned in the first direction (X-axis direction) or in the direction parallel to the substrate 110, and then bent toward one side in the third direction (Z-axis direction) after undergoing an ashing process (FIG. 15). In other words, in the process of fabricating the display device 10, the bending portion 161b may be extended and connected in the first direction (X-axis direction) from the flat portion 161p and then bent toward one side in the third direction (Z-axis direction) through a subsequent process. The fabricating process thereof will be described later in greater detail.

In an embodiment, a length L1b of the bending portion 161b of the first insulating pattern 161 in the third direction (Z-axis direction) may have a value of about 50 nanometers or greater and about 500 nanometers or less. In a case, for example, where the length L1b of the bending portion 161b has a value of about 50 nanometers or less or about 500 nanometers or greater, the shape of the bending portion 161b may not be formed in the illustrated shape, that is, the shape of the bending portion 161b may be different from that described above.

In an embodiment, the second insulating pattern 163 may have a flat portion 163p and a bending portion 163b. The flat portion 163p and the bending portion 163b are formed integrally with each other as a single unitary indivisible part, but may have different positional shapes. In an embodiment, for example, the flat portion 163p may be positioned or extending in the first direction (X-axis direction) or in a direction parallel to the substrate 110, and the bending portion 163b may be positioned or extending in the third direction (Z-axis direction) or in a direction perpendicular to the substrate 110.

The second insulating pattern 163 may have a similar shape to the first insulating pattern 161. In other words, the second insulating pattern 163 may have an ‘L’ shape or a shape mirror-symmetrical to the ‘L’ shape.

In an embodiment, the flat portion 163p may include a side surface 3pc facing the opening OP2. The side surface 3pc of the flat portion 163p may be in contact with the cathode electrode CE and may be entirely covered by the cathode electrode CE.

In an embodiment, the side surface 3pc of the flat portion 163p included in the second insulating pattern 163 and the side surface 1pc of the flat portion 161p included in the first insulating pattern 161 may be positioned on a same plane. The meaning of being positioned on a same plane as described above may have the same meaning as being aligned on a same plane and/or being positioned substantially on one extended imaginary plane.

In an embodiment, the bending portion 163b may extend from the flat portion 163p and may not be in contact with the element insulating layer 155. The bending portion 163b included in the second insulating pattern 163 may be bent in a same direction as the bending portion 161b included in the first insulating pattern 161.

In the process of fabricating the display device 10, the bending portion 163b may be temporarily positioned in the first direction (X-axis direction) or in the direction parallel to the substrate 110, and then bent toward one side in the third direction (Z-axis direction) by a subsequent ashing process (FIG. 15). In other words, in the process of fabricating the display device 10, the bending portion 163b may be extended and connected in the first direction (X-axis direction) from the flat portion 163p and then bent toward one side in the third direction (Z-axis direction) by a subsequent process. The fabricating process thereof will be described later in greater detail.

In an embodiment, a length L3b of the bending portion 163b of the second insulating pattern 163 in the third direction (Z-axis direction) may have a value of about 50 nanometers or greater and about 500 nanometers or less. In a case, for example, when the length L3 b of the bending portion 163 b has a value of about 50 nanometers or less or 500 nanometers or greater, the shape of the bending portion 163b may not be formed in the illustrated shape, that is, the shape of the bending portion 163b may be different from that described above.

In an embodiment, the element insulating layer 155 may cover the shape of the insulating pattern 160 with a uniform thickness. However, the meaning of uniform thickness as described above may include a process error of 10% or less.

The element insulating layer 155 may be in contact with and cover the insulating pattern 160, may extend from the insulating pattern 160 to cover the side surface e3 of the first light emitting layer EL1, and may extend from the side surface e3 of the first light emitting layer EL1 to cover a portion of the pixel defining layer 151. The element insulating layer 155 may entirely cover the side surface e3 of the first light emitting layer EL1.

The element insulating layer 155 may serve to effectively prevent the light emitting layer EL from being exposed to the atmosphere or environment during the process of fabricating the display device 10. The fabricating process thereof will be described later.

In an embodiment, the cathode electrode CE may entirely cover the element insulating layer 155 in a portion that does not overlap the opening OP2, and may extend from the element insulating layer 155 to cover the pixel defining layer 151.

The first encapsulation layer 171 according to an embodiment may entirely cover the cathode electrode CE, and the second encapsulation layer 173 may planarize a step (or a stepped structure) formed by the first encapsulation layer 171. Any repetitive detailed descriptions will be omitted.

Although features (or structures and characteristics) of the display element layer 150 positioned in a portion overlapping the first light emitting area EA1 is mainly illustrated and described above for convenience of description, it would be understood that the features of the display element layer 150 positioned in portions overlapping the second light emitting area EA2 and the third light emitting area EA3 may be the same as those of the display element layer 150 positioned in a portion overlapping the first light emitting area EA1.

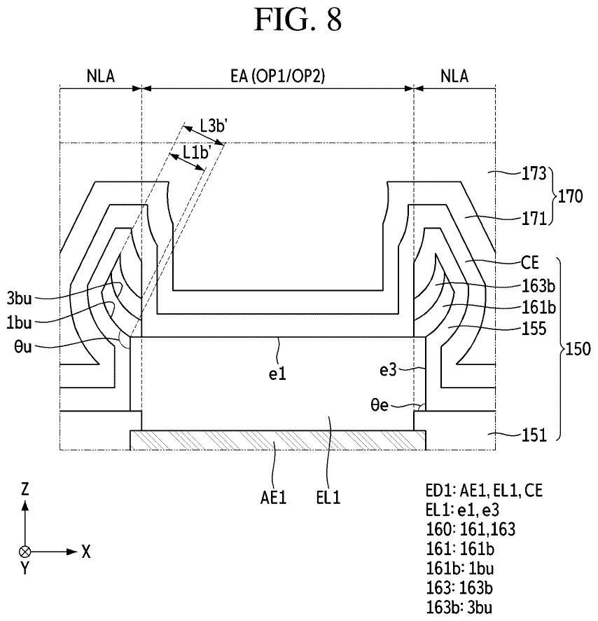

FIG. 7 is a schematic cross-sectional view taken along line X1-X1′ of FIG. 3 according to another embodiment and FIG. 8 is an enlarged schematic cross-sectional view of a display element layer overlapping a first light emitting area in FIG. 7.

Referring to FIGS. 7 and 8 in addition to FIGS. 1 to 6, a light emitting area EA included in a display device 30 may be defined by an opening OP. The opening OP may include an opening OP1 defined by a pixel defining layer 151 and an opening OP3 defined by an insulating pattern 160.

The insulating pattern 160 included in the display device 30 may have a different shape from the insulating pattern 160 included in the display device 10. Hereinafter, any repetitive detailed description of the same structure of the display device 30 as those of the display device 10 will be omitted and different structures will be mainly described.

In an embodiment, as shown in FIG. 8, a first light emitting layer EL1 included in the display device 30 may include an upper surface e1 and a side surface e3. The upper surface e1 may be one surface facing the cathode electrode CE, and the side surface e3 may be one surface facing the element insulating layer 155 in a portion toward the non-light emitting area NLA. The upper surface e1 and the side surface e3 may be connected to each other.

The side surface e3 of the first light emitting layer EL1 may be an inclined surface. The side surface e3 of the first light emitting layer EL1 may have a high taper angle. In an embodiment, for example, an inclination angle θe formed by the side surface e3 of the first light emitting layer EL1 and one surface of the pixel defining layer 151 may be in a range from about 60 degrees or more to about 90 degrees or less. One surface of the pixel defining layer 151 described above may be one surface extending in the first direction (X-axis direction).

The upper surface e1 of the first light emitting layer EL1 may have a portion in contact with the cathode electrode CE and a portion in contact with the insulating pattern 160. Any repetitive detailed descriptions thereof will be omitted.

The insulating pattern 160 included in the display device 30 may define the opening OP3. The insulating pattern 160 may be positioned to surround the opening OP3. The insulating pattern 160 may expose the light emitting layer EL in a portion overlapping the opening OP3.

In an embodiment, the opening OP1 defined by the pixel defining layer 151 and the opening OP3 defined by the insulating pattern 160 are the same as each other as shown in FIG. 7, but the present disclosure is not limited thereto.

Tensile stress in the second insulating pattern 163 may be greater than tensile stress in the first insulating pattern 161. Any repetitive detailed descriptions thereof will be omitted.

Accordingly, the first insulating pattern 161 and the second insulating pattern 163 included in the display device 30 may include a bending portion bent toward one side in the third direction (Z-axis direction).

The first insulating pattern 161 included in the display device 30 may include a bending (or curved) portion 161b. In an embodiment, for example, the first bending portion 161b may be bent toward one side in the third direction (Z-axis direction).

The bending portion 161b included in the display device 30 may include a first surface 1bu. The first surface 1bu of the bending portion 161b may be one surface facing the pixel defining layer 151. The first surface 1bu may be curved, and a slope of the first surface 1bu may become smaller (or thinner) as it moves toward the light emitting area EA.

An inclination angle θu formed by the first surface 1bu of the bending portion 161b included in the display device 30 and the side surface e3 of the first light emitting layer EL1 at a point where the first surface 1bu of the bending portion 161b included in the display device 30 and the side surface e3 of the first light emitting layer EL1 meat each other may be an obtuse angle.

In the process of fabricating the display device 30, the bending portion 161b included in the display device 30 may be temporarily positioned in the first direction (X-axis direction) or in the direction parallel to the substrate 110, and then bent toward one side in the third direction (Z-axis direction) by a subsequent ashing process (FIG. 15).

A tensile stress value of the second insulating pattern 163 included in the display device 30 and a stress property value of the first insulating pattern 161 may be different from each other. In other words, a bending shape of the insulating pattern 160 included in the display device 10 and a bending shape of the insulating pattern 160 included in the display device 30 may vary depending on the tensile stress of the first insulating pattern 161 and the second insulating pattern 163 included in each display device.

A length L1b′ of the bending portion 161b of the first insulating pattern 161 included in the display device 30 may have a value of about 50 nanometers or greater and about 500 nanometers or less. Any repetitive detailed descriptions thereof will be omitted.

The second insulating pattern 163 included in the display device 30 may include a bending portion 163b. In an embodiment, for example, the second bending portion 163b may be bent toward one side in the third direction (Z-axis direction).

The second insulating pattern 163 included in the display device 30 may have a similar shape to the first insulating pattern 161. In other words, the bending portion 163b included in the second insulating pattern 163 may be bent in a same direction as the bending portion 161b included in the first insulating pattern 161.

In the process of fabricating the display device 30, the bending portion 163b included in the display device 30 may be temporarily positioned in the first direction (X-axis direction) or in the direction parallel to the substrate 110, and then bent toward one side in the third direction (Z-axis direction) by a subsequent process.

The bending portion 163b included in the display device 30 may include a first surface 3bu. The first surface 3bu of the bending portion 163b may be one surface of the bending portion 163b in contact with the first insulating pattern 161. The first surface 3bu may be curved, and a slope of the first surface 3bu may become smaller (or thinner) as it moves toward the light emitting area EA.

A length L3b′ of the bending portion 163b of the second insulating pattern 163 included in the display device 30 may have a value of about 50 nanometers or greater and about 500 nanometers or less.

In an embodiment, an element insulating layer 155 may be further included in the display device 30 to cover the shape of the insulating pattern 160 included in the display device 30 with a uniform thickness. However, the meaning of uniform thickness as described above may include a process error of 10% or less.

The element insulating layer 155 and the cathode electrode CE included in the display device 30 may have the same structure and characteristics as the element insulating layer 155 and the cathode electrode CE included in the display device 10. Any repetitive detailed descriptions thereof will be omitted.

The display device 30 according to an embodiment may assist in minimizing a spacing distance W3 between the first to third light emitting layers EL1, EL2, and EL3 by forming the insulating pattern 160 to be bent toward one side in the third direction (Z-axis direction).

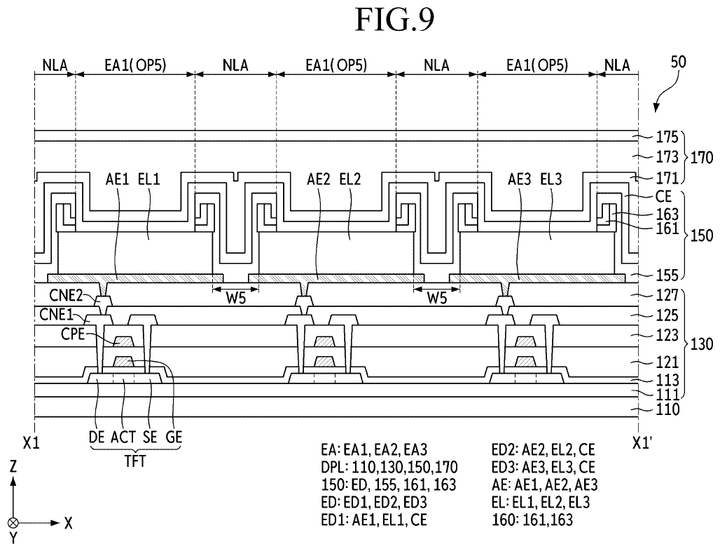

FIG. 9 is a schematic cross-sectional view taken along line X1-X1′ of FIG. 3 according to another embodiment.

Referring to FIG. 9 in addition to FIGS. 1 to 8, a display element layer 150 included in a display device 50 shown in FIG. 9 may have a different shape from the display element layer 150 included in the display device 10 shown in FIG. 4. Hereinafter, any repetitive detailed description of the same or like structure of the display device 50 as that of the display device 10 will be omitted and different structures will be mainly described.

In an embodiment, the display element layer 150 included in the display device 50 may be positioned on the second via layer 127. The display element layer 150 may include a light emitting element ED, an element insulating layer 155, and an insulating pattern 160. In such an embodiment, a pixel defining layer 151 shown in FIG. 4 may be omitted.

A light emitting layer EL included in the display device 50 may be positioned in contact with the anode electrode AE. A width of the light emitting layer EL included in the display device 50 in the first direction (X-axis direction) may be smaller than a width of the anode electrode AE. Accordingly, a portion of the anode electrode AE included in the display device 50 may be exposed without being covered by the light emitting layer EL.

A first light emitting layer EL1, a second light emitting layer EL2, and a third light emitting layer EL3 included in the display device 50 may be spaced apart from each other with the element insulating layer 155.

The light emitting layer EL included in the display device 50 may be formed through a photo lithography process during the fabricating process, and accordingly, the light emitting layer EL included in the display device 50 may have a same side shape as the light emitting layer EL included in the display device 10 described above. Any repetitive detailed descriptions thereof will be omitted.

The element insulating layer 155 included in the display device 50 may define the opening OP5. The light emitting area EA included in the display device 50 may be defined by the opening OP5.

The element insulating layer 155 included in the display device 50 may expose the light emitting layer EL in a portion overlapping the opening OP5, and may be positioned to surround the opening OP5.

The element insulating layer 155 included in the display device 50 may be in contact with and cover the insulating pattern 160 in a portion overlapping the non-light emitting area NLA. By extending from the insulating pattern 160, the element insulating layer 155 included in the display device 50 may be in contact with and cover a side surface of the light emitting layer EL and the anode electrode AE in a portion overlapping the non-light emitting area NLA.

The element insulating layer 155 included in the display device 50 may insulate and separate the first anode electrode AE1, the second anode electrode AE2, and the third anode electrode AE3 from each other.

The insulating pattern 160 included in the display device 50 may have a same shape as the insulating pattern 160 included in the display device 10. In an embodiment, the insulating pattern 160 included in the display device 50 may include a first insulating pattern 161 and a second insulating pattern 163, and the first insulating pattern 161 and the second insulating pattern 163 may include a bending portion bent in a direction toward one side in the third direction (Z-axis direction). Any repetitive detailed descriptions thereof will be omitted.

A cathode electrode CE included in the display device 50 may be in contact with the light emitting layer EL in a portion overlapping the opening OP5 and may entirely cover the element insulating layer 155 in a portion overlapping the non-light emitting area NLA. The cathode electrode CE included in the display device 50 may be spaced apart from the anode electrode AE by the element insulating layer 155. Any repetitive detailed descriptions thereof will be omitted.

The display device 50 according to an embodiment may assist in minimizing a spacing distance W5 between the first to third light emitting layers EL1, EL2, and EL3 by forming the insulating pattern 160 to be bent toward one side in the third direction (Z-axis direction) and forming the element insulating layer 155 to cover the insulating pattern 160 and the light emitting layer EL while separating and insulating the anode electrode AE.

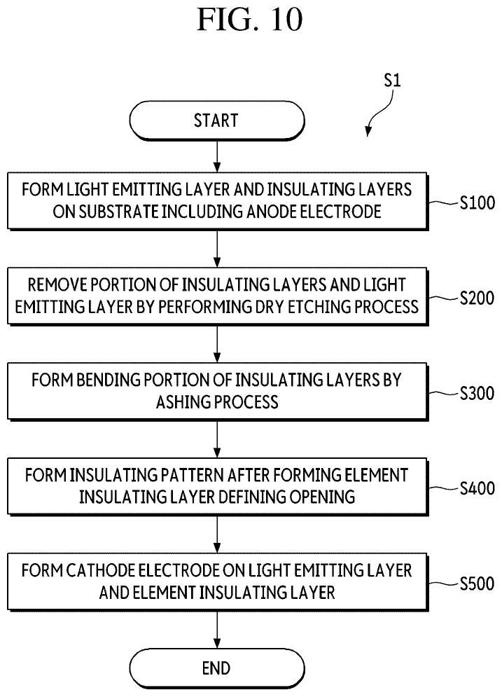

FIG. 10 is a flowchart illustrating a method for fabricating the display element layer of FIG. 4.

Referring to FIG. 10, a method (S1) for fabricating a display element layer 150 included in a display device 10 according to an embodiment may include a process (S100) of forming a light emitting layer and insulating layers on a substrate including an anode electrode, a process (S200) of removing a portion of the insulating layers and the light emitting layer by performing a dry etching process, a process (S300) of forming a bending portion of the insulating layers by performing an ashing process, a process (S400) of forming an insulating pattern after forming an element insulating layer defining an opening, and a process (S500) of forming a cathode electrode on the light emitting layer and the element insulating layer.

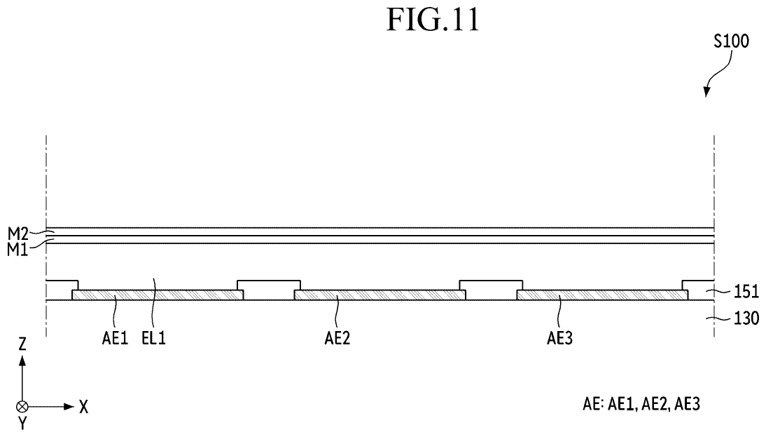

FIG. 11 is a cross-sectional view illustrating process S100 of FIG. 10.

The process (S100) of forming a light emitting layer and insulating layers on a substrate including an anode electrode will be described with reference to FIG. 11.

In an embodiment of a method for fabricating a display element layer, a plurality of anode electrodes AE are formed on a thin film transistor layer 130. The anode electrodes AE may include a first anode electrode AE1, a second anode electrode AE2, and a third anode electrode AE3, and the first anode electrode AE1, the second anode electrode AE2, and the third anode electrode AE3 may be spaced apart from each other with a pixel defining layer 151.

In this process, the process of forming the anode electrode AE may be performed through a film forming process (e.g., sputtering) of forming at least one selected from the above-mentioned metal materials and a patterning process (e.g., an etching process) of the metal material.

Although not illustrated in the drawing, the thin film transistor layer 130 may be arranged on the substrate 110, and a structure of the thin film transistor layer 130 is the same as that described above with reference to FIG. 4. Any repetitive detailed descriptions thereof will be omitted.

Next, a first light emitting layer EL1 is formed on the anode electrode AE. The first light emitting layer EL1 may cover the anode electrode AE and the thin film transistor layer 130. The process of forming the first light emitting layer EL1 according to an embodiment may be performed through a thermal evaporation method. This process may be performed without using a separate fine metal mask. Therefore, the first light emitting layer EL1 may entirely cover the anode electrode AE and the thin film transistor layer 130.

Next, a first insulating layer M1 and a second insulating layer M2 are sequentially stacked on the first light emitting layer EL1. The first insulating layer M1 and the second insulating layer M2 may be in contact with and entirely cover the first light emitting layer EL1. In this process, the first insulating layer M1 and the second insulating layer M2 may perform a function of a hard mask.

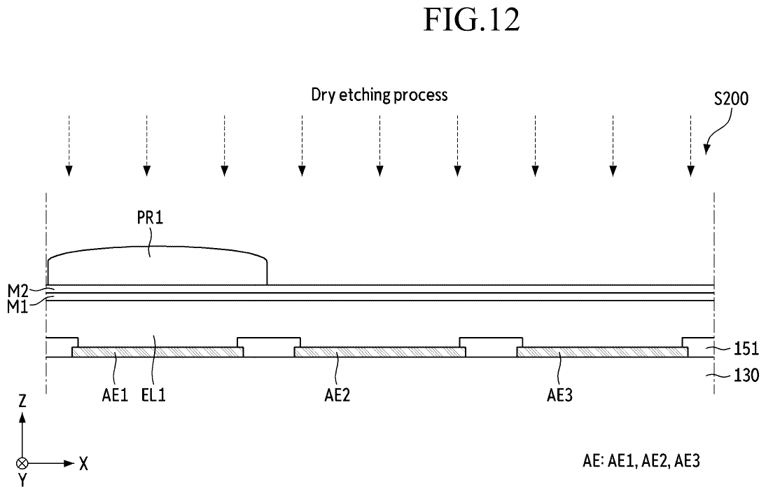

FIGS. 12 to 14 are cross-sectional views illustrating process S200 of FIG. 10.

The process (S200) of removing a portion of the insulating layers and the light emitting layer by performing a dry etching process will be described with reference to FIGS. 12 to 14.

In an embodiment of a method for fabricating a display element layer, a photoresist PR1 is formed on the second insulating layer M2, and a dry etching process is performed using the photoresist PR1 as a mask.

In an embodiment, for example, the dry etching process may be performed through a reactive ion etching (RIE) process using reactive gases such as CHF₃, CH₃F, CH₂F₂, CHF₆, CF₄, C₂F₆, and C₃F₆, and sputtering gases such as Ar, and O₂/Ar. In this case, an inductively coupled plasma (ICP) source or a capacitively coupled plasma (CCP) source may be used as a plasma source.

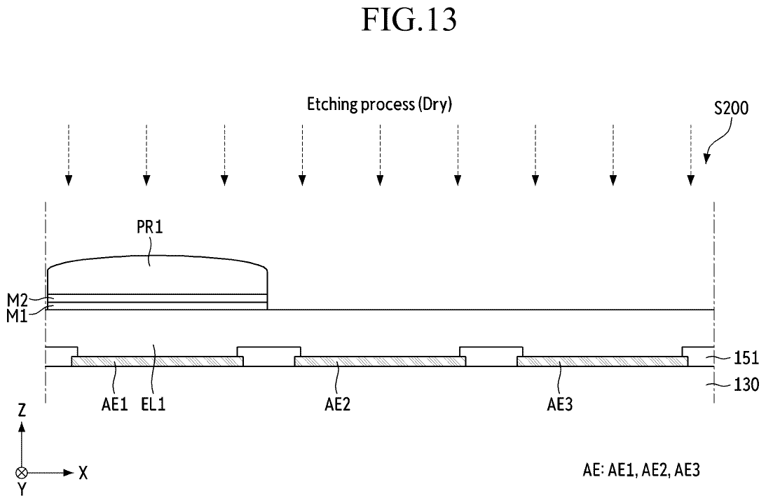

In this process, as shown in FIG. 13, the photoresist PR1 may be positioned in a portion overlapping the first anode electrode AE1. The dry etching process may be performed by being divided into two processes.

Firstly, the first insulating layer M1 and the second insulating layer M2 are removed.

In this process, as shown in FIG. 13, portions of the first insulating layer M1 and the second insulating layer M2 that do not overlap the photoresist PR1 may be simultaneously removed. In an embodiment, for example, the portions of the first insulating layer M1 and the second insulating layer M2 that do not overlap the photoresist PR1 may be isotropically removed. Accordingly, the first light emitting layer EL1 that does not overlap the photoresist PR1 may be exposed.

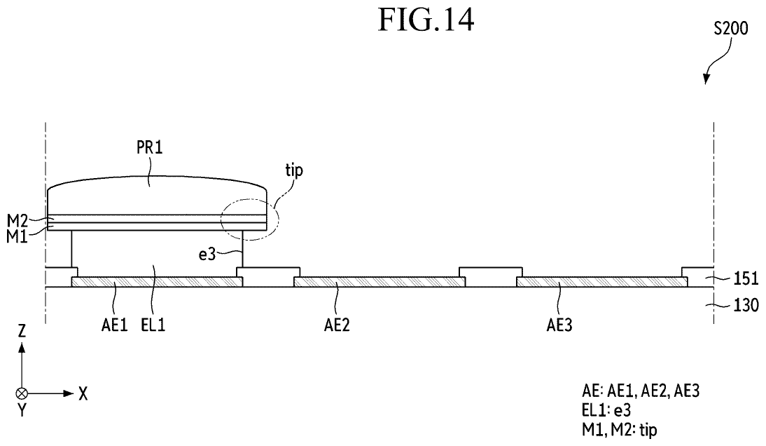

Next, secondly, the first light emitting layer EL1 is removed as shown in FIG. 14.

In this process, the process of removing the first light emitting layer EL1 and the process of removing the first insulating layer M1 and the second insulating layer M2 may use different process gases.

In this process, a portion of the first light emitting layer EL1 that does not overlap the photoresist PR1 may be removed, thereby exposing the second anode electrode AE2 and the third anode electrode AE3.

In this process, a side surface e3 of the first light emitting layer EL1 may be an inclined surface, may have a high taper angle, and may have a clear cross-section without tail defects. Any repetitive detailed descriptions thereof will be omitted.

In this process, as shown in FIG. 14, the first insulating layer M1 and the second insulating layer M2 may have a tip that protrudes further than the side surface e3 of the first light emitting layer EL1. The tip included in the first insulating layer M1 and the second insulating layer M2 may be a portion protruding in the first direction (X-axis direction). Accordingly, an undercut may be formed between the side surface e3 of the first light emitting layer EL1 and the first insulating layer M1. The second insulating layer M2 may be positioned in contact with the photoresist PR1.

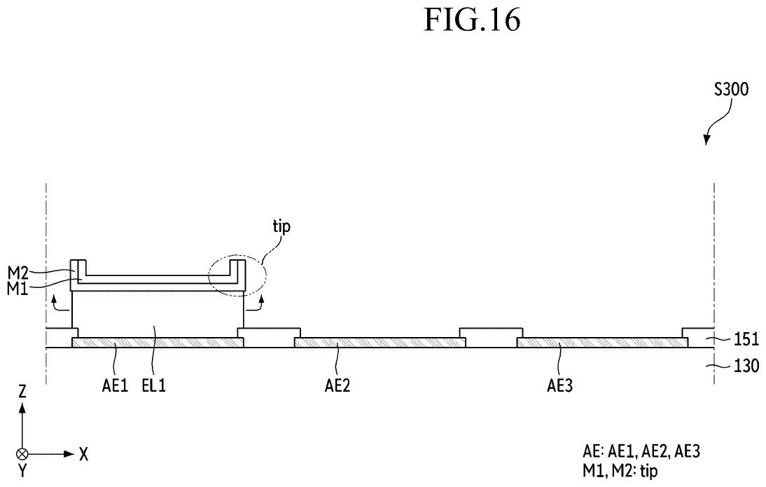

FIGS. 15 and 16 are cross-sectional views illustrating process S300 of FIG. 10.

The process (S300) of forming a bending portion of the insulating layers by performing an ashing process will be described with reference to FIGS. 15 and 16.

In an embodiment, as shown in FIGS. 15 and 16, the photoresist PR1 is removed by performing an ashing process. In this process, the photoresist PR1 may be removed, and the first light emitting layer EL1 may be protected by the first insulating layer M1 and the second insulating layer M2 that function as the hard mask.

As described above, in the display device 10 according to an embodiment, the first insulating layer M1 and the second insulating layer M2 having the bending portion may be formed without a separate additional process by forming the second insulating pattern 163 having a relatively large tensile stress value to be in contact with the first insulating pattern 161. Accordingly, in this process, the tips of the first insulating layer M1 and the second insulating layer M2 may be bent in a direction toward one side in the third direction (Z-axis direction).

In this process, depending on the stress properties of each of the first insulating layer M1 and the second insulating layer M2, the tips of the first insulating layer M1 and the second insulating layer M2 may be formed in the shape of the insulating pattern 160 as illustrated in FIG. 7.

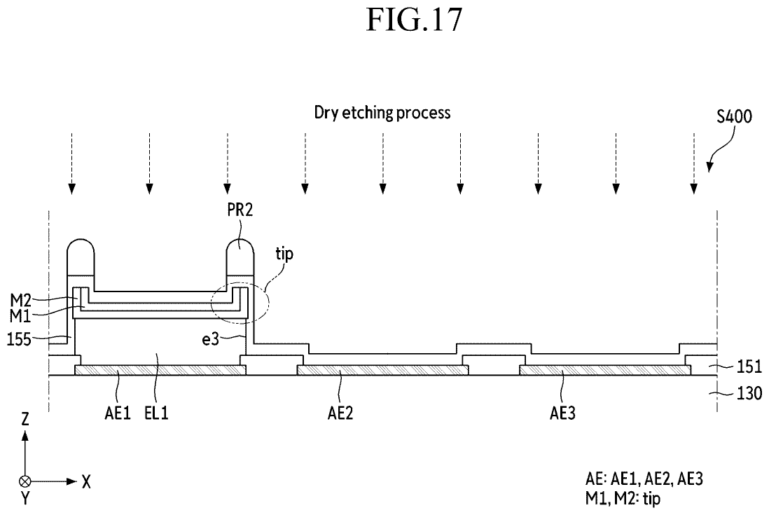

FIGS. 17 to 20 are cross-sectional views illustrating process S400 of FIG. 10.

The process (S400) of forming an insulating pattern after forming an element insulating layer defining an opening will be described with reference to FIGS. 17 to 20.

In an embodiment, an element insulating layer 155 that entirely covers the first light emitting layer EL1, the first insulating layer M1, and the second insulating layer M2 is formed. In this process, the element insulating layer 155 may entirely cover the second anode electrode AE2, the third anode electrode AE3, and the pixel defining layer 151.

In this process, the process of forming the element insulating layer 155 may be performed through a film forming process (e.g., a deposition process) of forming at least one selected from the above-mentioned metal materials and a patterning process (e.g., an etching process) of the metal material.

In this process, the element insulating layer 155 may effectively prevent exposure of the first light emitting layer EL1 to the atmosphere or the process environment.

Next, after forming a photoresist PR2 on the element insulating layer 155 in a portion overlapping the tips of the first insulating layer M1 and the second insulating layer M2, a dry etching process is performed.

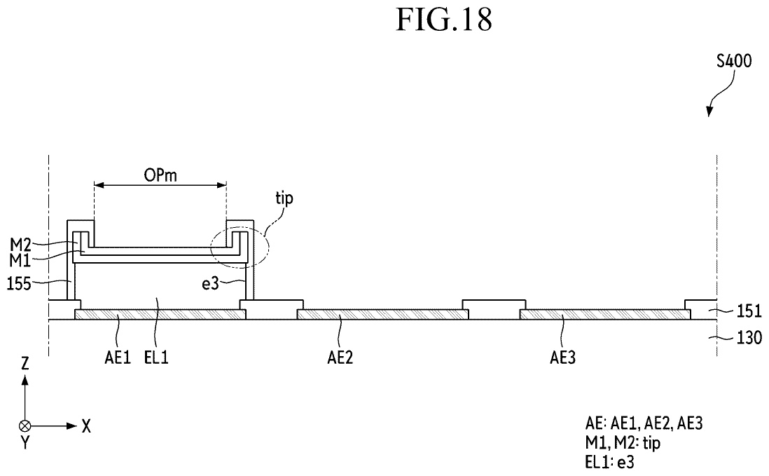

In this process, the element insulating layer 155 that does not overlap the photoresist PR2 may be completely removed, and thus, the element insulating layer 155 may be formed in the shape illustrated in FIG. 18.

In an embodiment, the element insulating layer 155 may define a temporary opening OPm and expose the second insulating layer M2 in a portion overlapping the temporary opening OPm. The element insulating layer 155 may be positioned to surround the temporary opening OPm.

The element insulating layer 155 may entirely cover the tips of the first insulating layer M1 and the second insulating layer M2, and may extend from the tips of the first insulating layer M1 and the second insulating layer M2 to entirely cover the side surface e3 of the first light emitting layer EL1. In addition, the element insulating layer 155 may be in contact with the pixel defining layer 151.

In this process, the second anode electrode AE2, the third anode electrode AE3, and the pixel defining layer 151 may be exposed again. Although not illustrated in the drawing, the photoresist PR2 is removed by performing an ashing process.

Thereafter, by repeating the same process described above, a second light emitting layer EL2, a first insulating layer M1, a second insulating layer M2, and an element insulating layer 155 are formed on the second anode electrode AE2, and by repeating the same process again, a third light emitting layer EL3, a first insulating layer M1, a second insulating layer M2, and an element insulating layer 155 are formed on the third anode electrode AE3. Any repetitive detailed descriptions thereof will be omitted.

In this process, the first insulating layer M1, the second insulating layer M2 and the element insulating layer 155 covering the first anode electrode AE1 and the first light emitting layer EL1, the first insulating layer M1, the second insulating layer M2 and the element insulating layer 155 covering the second anode electrode AE2 and the second light emitting layer EL2, and the first insulating layer M1, the second insulating layer M2 and the element insulating layer 155 covering the third anode electrode AE3 and the third light emitting layer EL3 may be spaced apart from each other.

As the display device 10 according to an embodiment includes the first insulating layer M1 and the second insulating layer M2 covering the upper surface of the light emitting layer EL and the element insulating layer 155 covering the side surface of the light emitting layer EL in the fabricating process, damage defects to the light emitting layer EL may be effectively prevented from occurring even during the repeatedly performed etching process. Therefore, the display device 10 according to an embodiment may be easily or efficiently fabricated.

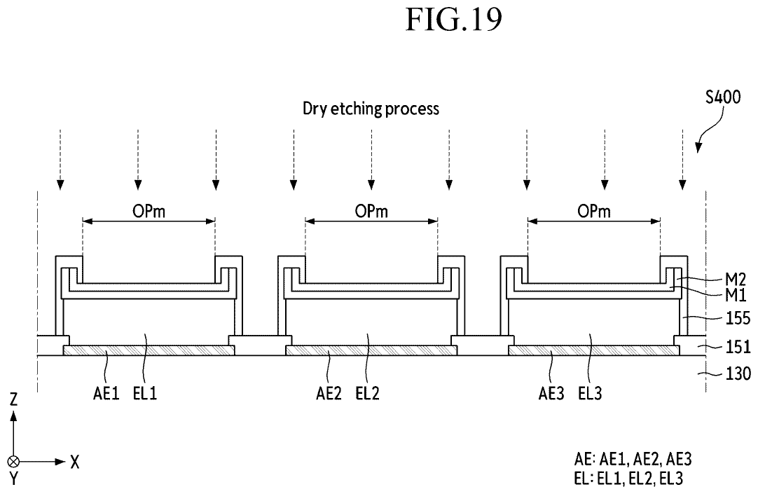

Next, as shown in FIG. 19, the first insulating layer M1 and the second insulating layer M2 positioned in the portion overlapping the temporary opening OPm are removed by performing a dry etching process.

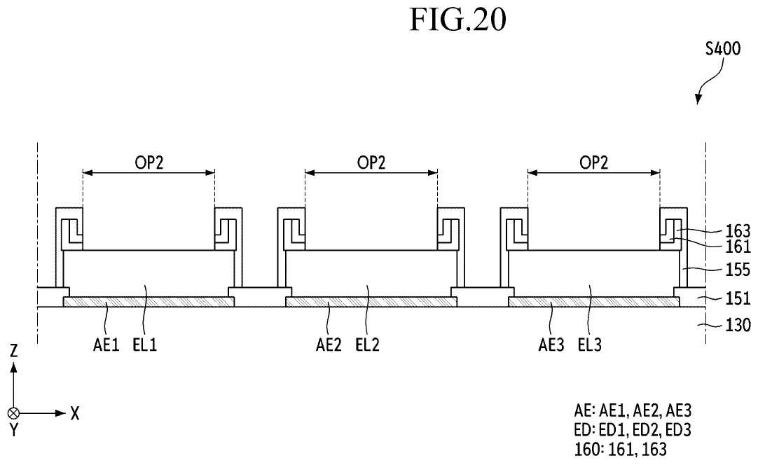

In this process, the first insulating layer M1 may be formed in the shape of the first insulating pattern 161 as illustrated in FIG. 20, and the second insulating layer M2 may be formed in the shape of the second insulating pattern 163 as illustrated in FIG. 20. As a result, the insulating pattern 160 illustrated in FIG. 4 may be formed.

In this process, the opening OP2 may be formed in the element insulating layer 155 may form as illustrated in FIG. 4. The insulating pattern 160 may be positioned to surround the opening OP2, and the light emitting layer EL may be exposed in a portion overlapping the opening OP2.

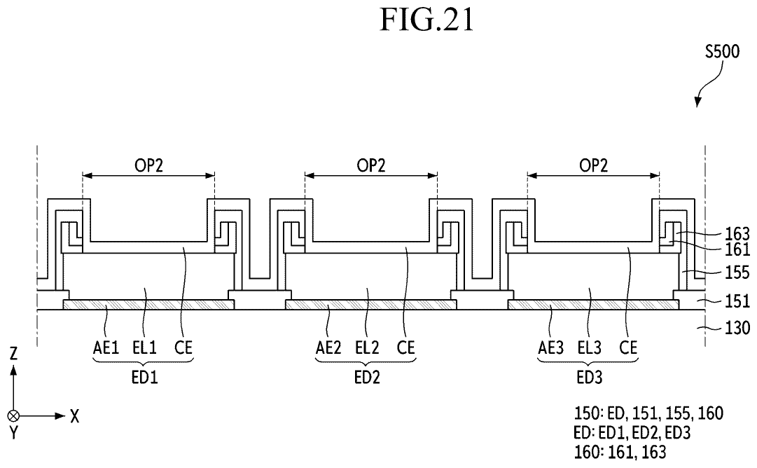

FIG. 21 is a cross-sectional view illustrating process S500 of FIG. 10.

The process (S500) of forming a cathode electrode on the light emitting layer and the element insulating layer will be described with reference to FIG. 21.

In this process, the process of forming the cathode electrode CE may be performed by a sputtering process. This process may be performed in a vacuum chamber.

In this process, the cathode electrode CE may be in contact with the first light emitting layer EL1, the second light emitting layer EL2, and the third light emitting layer EL3 in a portion overlapping the opening OP2, and may extend from the portion overlapping the opening OP2 to cover the element insulating layer 155 and the pixel defining layer 151 in a portion overlapping the non-light emitting area NLA.

As a result, the display element layer 150 illustrated in FIG. 4 may be formed.

The display device 10 according to an embodiment may form the insulating pattern 160 having the bending portion without a separate process by forming or setting the tensile stress in the second insulating pattern 163 to be greater than the tensile stress in the first insulating pattern 161.

Specifically, in the process of fabricating the display device 10, the second insulating pattern 163 may be bent toward one side in the third direction (Z-axis direction) or toward a direction perpendicular to the substrate 110, and accordingly, the first insulating pattern 161 positioned in contact with the second insulating pattern 163 may also be bent in the same direction. Accordingly, the display device 10 according to an embodiment may be easily or efficiently fabricated.

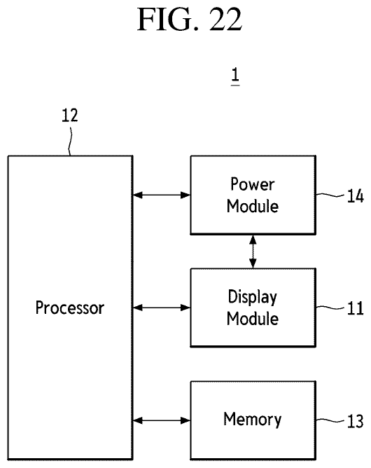

FIG. 22 is a block diagram of an electronic device according to an embodiment.

Referring to FIG. 22 in addition to FIGS. 1 to 21, the display device 10, 30, or 50 according to embodiments may be applied to various electronic devices 1. The electronic device 1 according to an embodiment may include the display device 10, 30 or 50 described above, and may further include a module or device having additional functions in addition to the display device 10, 30, or 50.

The electronic device 1 according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 1.

At least one of the components of the electronic device 1 described above may be included in the display device according to the above-described embodiments. In addition, some of the individual modules functionally included within one module may be included within the display device, while others may be provided separately from the display device. In an embodiment, for example, the display device includes the display module 11, and the processor 12, the memory 13 and the power module 14 may be provided in the form of other devices within the electronic device 1 other than the display device.

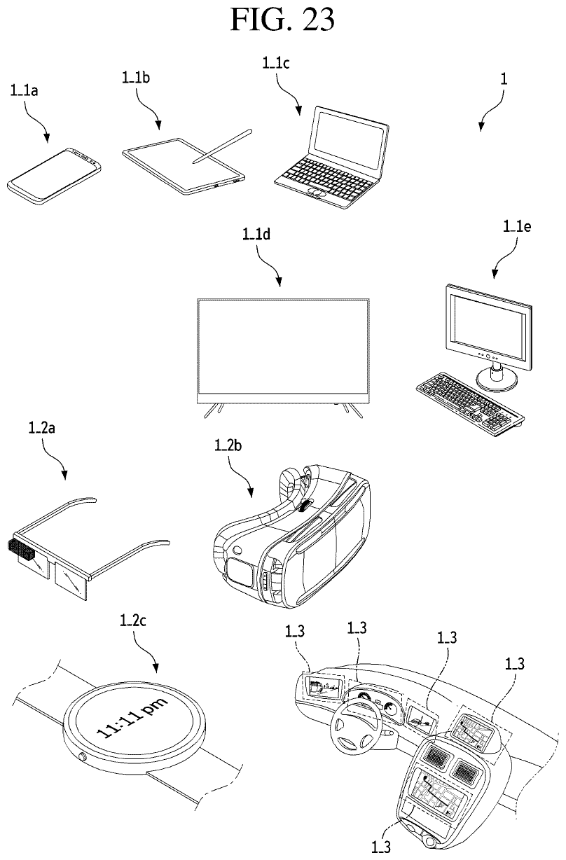

FIG. 23 illustrates schematic diagrams of electronic devices according to various embodiments.

Referring to FIG. 23 in addition to FIGS. 1 to 22, various electronic devices 1 to which the display device 10, 30, or 50 according to embodiments are applied may include not only an image display electronic device such as a smart phone 1_1a, a tablet personal computer (PC) 1_1b, a laptop 1_1c, a television (TV) 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a center information display (CID), a room mirror display, etc., arranged on a vehicle's instrument panel, center fascia, or dashboard.

According to a display device and a method of fabricating the display device according to embodiments, it is possible to provide a high-resolution image and solve a contact failure between an anode and a cathode.

However, the effects of the present disclosure are not restricted to the one set forth herein. The above and other effects of the present disclosure will become more apparent to one of daily skill in the art to which the present disclosure pertains by referencing the claims.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a light emitting area and a non-light emitting area;
an anode electrode disposed on one surface of the substrate to overlap the light emitting area;
a light emitting layer disposed on the anode electrode;
an element insulating layer disposed on the light emitting layer and defining an opening;
a cathode electrode disposed on the element insulating layer and in contact with the light emitting layer in a portion overlapping the opening; and
an insulating pattern disposed to surround the opening in a plan view and disposed between the light emitting layer and the element insulating layer,
wherein the insulating pattern includes a bending portion bent in a direction perpendicular to the one surface of the substrate.

2. The display device of claim 1, wherein the insulating pattern is in contact with the light emitting layer, the cathode electrode, and the element insulating layer, and
the insulating pattern is completely surrounded by the light emitting layer, the cathode electrode, and the element insulating layer.

3. The display device of claim 2, wherein a length of the bending portion of the insulating pattern is about 50 nanometers or greater and about 500 nanometers or less.

4. The display device of claim 1, wherein the insulating pattern includes at least one selected from silicon nitride, silicon oxide, and silicon oxynitride.

5. The display device of claim 4, wherein the insulating pattern includes:
a first insulating pattern in contact with the light emitting layer; and
a second insulating pattern disposed between the first insulating pattern and the element insulating layer.

6. The display device of claim 5, wherein a tensile stress value of the second insulating pattern is greater than a tensile stress value of the first insulating pattern.

7. The display device of claim 6, wherein a first bending portion included in the first insulating pattern and a second bending portion included in the second insulating pattern are in contact with each other, and
the first bending portion and the second bending portion are bent in a same direction.

8. The display device of claim 1, wherein a side surface of the insulating pattern facing the opening is completely covered by the cathode electrode.

9. The display device of claim 1, wherein an inclined angle formed by the one surface of the substrate and a side surface of the light emitting layer is about 60 degrees or greater and about 90 degrees or less.

10. The display device of claim 9, wherein the element insulating layer is in contact with and covers the insulating pattern and the side surface of the light emitting layer.

11. The display device of claim 10, wherein the bending portion of the insulating pattern protrudes further in a direction toward the non-light emitting area than the side surface of the light emitting layer does.

12. The display device of claim 1, further comprising a pixel definition layer covering an edge of the anode electrode and defining an opening,
wherein a portion of the light emitting layer in the opening defined by the pixel defining layer is in contact with the anode electrode, and
a portion of the light emitting layer exposed through the opening defined by the element insulating layer is in contact with the cathode electrode.

13. A method for fabricating a display device, the method comprising:
forming a light emitting layer and insulating layers on a substrate including an anode electrode;
removing a portion of the insulating layers and the light emitting layer by performing a dry etching process;
forming a bending portion of the insulating layers by performing an ashing process;
forming an insulating pattern after forming an element insulating layer defining an opening; and
forming a cathode electrode on the light emitting layer and the element insulating layer,
wherein the insulating layers includes a first insulating layer and a second insulating layer, and
a tensile stress value of the second insulating layer is greater than a tensile stress of the first insulating layer.

14. The method of claim 13, wherein in the forming the bending portion of the insulating layers by performing the ashing process, edges of the first insulating layer and the second insulating layer are bent in a direction perpendicular to one surface of the substrate.

15. An electronic device comprising:
a display device including a substrate including a light emitting area and a non-light emitting area; and
at least one selected from a display module, a processor, a memory, and a power module, which is connected to the display device,
wherein the display device includes:
an anode electrode disposed on one surface of the substrate to overlap the light emitting area;
a light emitting layer disposed on the anode electrode;
an element insulating layer disposed on the light emitting layer and defining an opening;
a cathode electrode disposed on the element insulating layer and in contact with the light emitting layer in a portion overlapping the opening; and
an insulating pattern disposed to surround the opening in a plan view and disposed between the light emitting layer and the element insulating layer, and
the insulating pattern includes a bending portion bent in a direction perpendicular to the one surface of the substrate.

16. The electronic device of claim 15, wherein the insulating pattern is in contact with the light emitting layer, the cathode electrode, and the element insulating layer, and
the insulating pattern is completely surrounded by the light emitting layer, the cathode electrode, and the element insulating layer.

17. The electronic device of claim 16, wherein a length of the bending portion of the insulating pattern is about 50 nanometers or greater and about 500 nanometers or less.

18. The electronic device of claim 15, wherein the insulating pattern includes at least one selected from silicon nitride, silicon oxide, and silicon oxynitride.

19. The electronic device of claim 18, wherein the insulating pattern includes:
a first insulating pattern in contact with the light emitting layer; and
a second insulating pattern disposed between the first insulating pattern and the element insulating layer.

20. The electronic device of claim 19, wherein a tensile stress value of the second insulating pattern is greater than a tensile stress value of the first insulating pattern.
